(19) United States
(12) Patent Application Publication
(10) Pub. No.: US 2015/0008199 A1
(43) Pub. Date: Jan. 8, 2015

(54) MOUNTING APPARATUS FOR STORAGE DEVICE

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: WEN-DA ZHANG, Shenzhen (CN); XIU-QUAN HU, Shenzhen (CN); YU-WEI HE, Shenzhen (CN); YAN-JUN ZHANG, Shenzhen (CN)

(21) Appl. No.: 14/318,928

(22) Filed: Jun. 30, 2014

(30) Foreign Application Priority Data
Jul. 3, 2013 (CN) 2013102765709

(51) Int. Cl. H05K 7/18; H05K 5/02; H05K 7/02

(52) U.S. Cl. CPC H05K 7/183; H05K 7/023; H05K 5/0217
USPC 211/41.12

(57) ABSTRACT

Mounting apparatus includes an enclosure, a tray, and a securing member. The enclosure includes a side plate, and a fixing portion is defined in the enclosure. The tray secures a first storage device and is slidable in a first direction that is substantially parallel to the side plate to engage with the side plate. The securing member includes a first limiting portion and a securing portion. The first limiting portion is engaged with the tray, and the securing portion is engaged with the fixing portion to prevent the first limiting portion from disengaging from the tray.

### FIELD

The present disclosure relates to mounting apparatuses, and particularly to a mounting apparatus for mounting a plurality of storage devices in a server.

### BACKGROUND

Many servers include data storage devices such as hard disk drives (HDDs), floppy disk drives, and compact disc-read only memory (CD-ROM) drives. Data storage devices are received in a bracket that is attached to a server enclosure. A screw can be used to attach the bracket.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus in accordance with an embodiment.

FIG. 2 is similar to FIG. 1, but viewed from a different angle.

FIG. 3 is an isometric view of a securing member of the mounting apparatus of FIG. 1.

FIG. 4 is an assembled view of the mounting apparatus of FIG. 1.

FIG. 5 is a side view of the mounting apparatus of FIG. 4.

FIG. 6 is a top view of the mounting apparatus of FIG. 4.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

The present disclosure is described in relation to a mounting apparatus comprising an enclosure, a tray, and a securing member. The enclosure comprises a side plate, and a fixing portion is defined in the enclosure. The tray secures a first storage device and is slidable in a first direction that is substantially parallel to the side plate to engage with the side plate. The securing member comprises a first limiting portion and a securing portion. The first limiting portion is engaged with the tray, and the securing portion is engaged with the fixing portion to prevent the first limiting portion from disengaging from the tray.

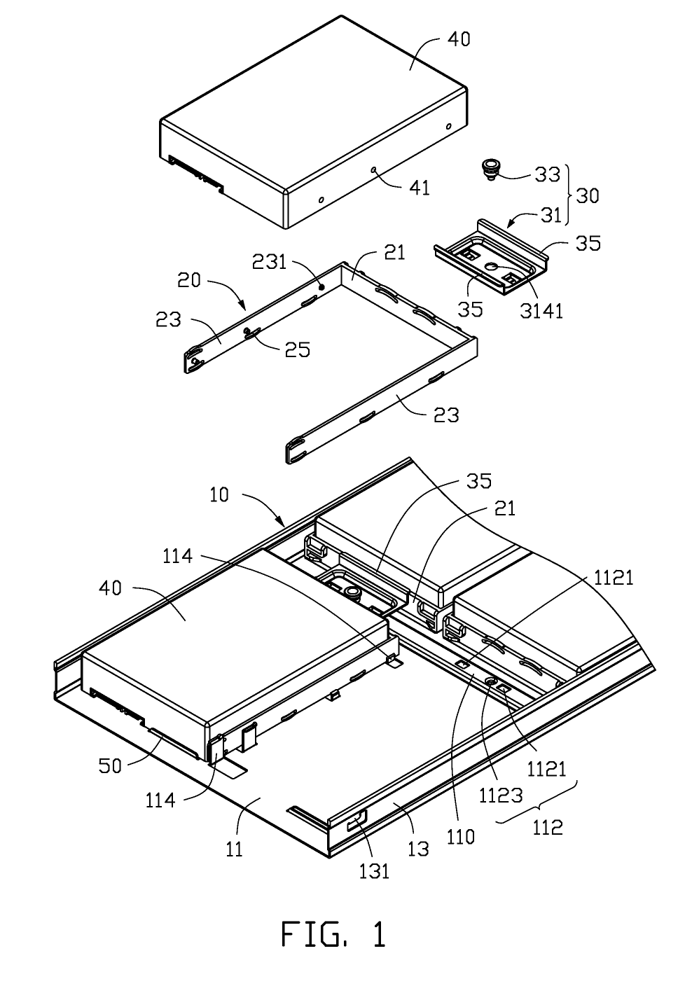

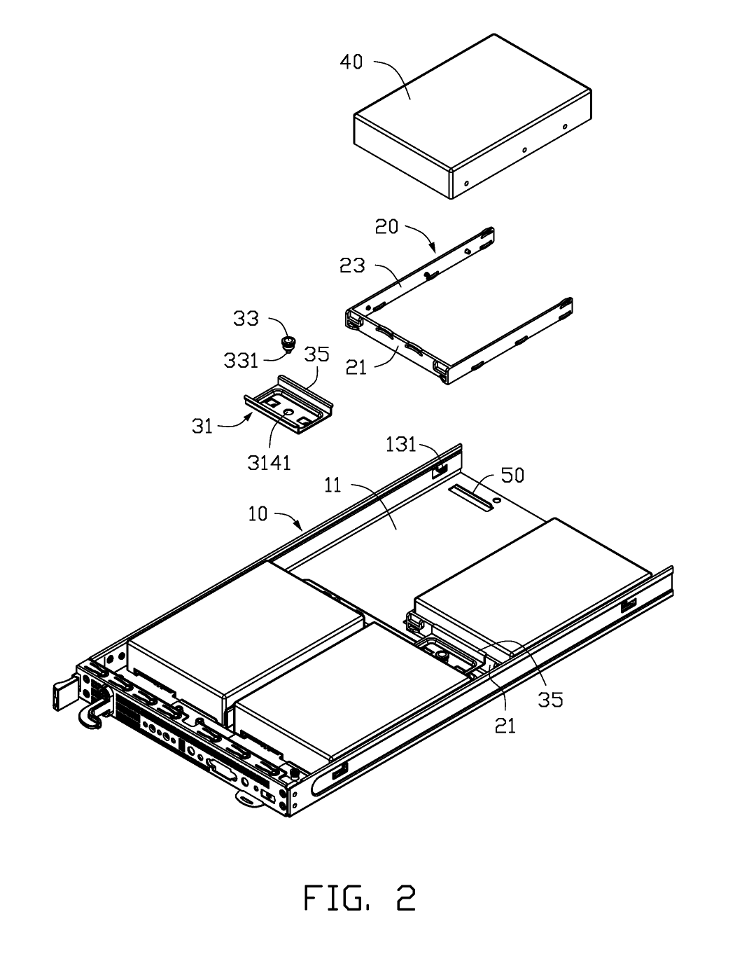

FIGS. 1-3 illustrate an embodiment of a mounting apparatus comprising an enclosure 10, a plurality of trays 20 received in the enclosure 10, and two securing members 30 attached to the enclosure 10. A storage device 40 is located in each tray 20 and each storage device 40 defines a plurality of mounting holes 41. In at least one embodiment, the storage devices 40 can be hard disk drives (HDDs), floppy disk drives, and compact disc-read only memory (CD-ROM) drives.

The enclosure 10 comprises a bottom plate 11 and two side plates 13 coupled to the bottom plate 11. In at least one embodiment, each side plate 13 is substantially perpendicular to the bottom plate 11. A first clipping portion 131 is located on each side plate 13, and a plurality of second clipping portions 114 is located on the bottom plate 11. Each second clipping portion 114 can be a hook. The bottom plate 11 defines a sliding passage 110. Two clipping assemblies 112 are located in the sliding passage 110. Each clipping assembly 112 comprises two clamping holes 1121 and a fixing portion 1123 located between the two clamping holes 1121. The fixing portion 1123 can be a fixing hole. A blocking member 50 can be located on the bottom plate 11. In at least one embodiment, the blocking member 50 is substantially perpendicular to the bottom plate 11 and the side plate 13.

Each tray 20 comprises a front panel 21 and two side panels 23 coupled to the front panel 21. In at least one embodiment, each side panel 23 is substantially perpendicular to the front panel 21. A plurality of mounting posts 231 is located on each side panel 23 and corresponds to the mounting holes 41. A plurality of vibration absorbing portions 25 is located on the tray 20. In at least one embodiment, each vibration absorbing portion 25 is arcuate.

Each securing member 30 comprises a main body 31, with a securing portion 33 and two limiting portions 35 located on the main body 31. The main body 31 comprises a securing panel 311 and two connecting panels 313 coupled to the securing panel 311. In at least one embodiment, each connecting panel 313 is substantially perpendicular to the securing panel 311, and each limiting portion 35 extends perpendicularly from each connecting panel 313. A sliding portion 314 is located on the securing panel 311 and can be slidably received in the sliding passage 110. The sliding portion 314 comprises a through hole 3141 and two clamping pieces 3143 on opposite sides of the through hole 3141. The through hole 3141 can receive the securing portion 33, and the clamping pieces 3143 can clip into the clamping holes 1121. In at least one embodiment, the securing portion 33 is a spring pin, and a fastening portion 331 is defined in the spring pin.

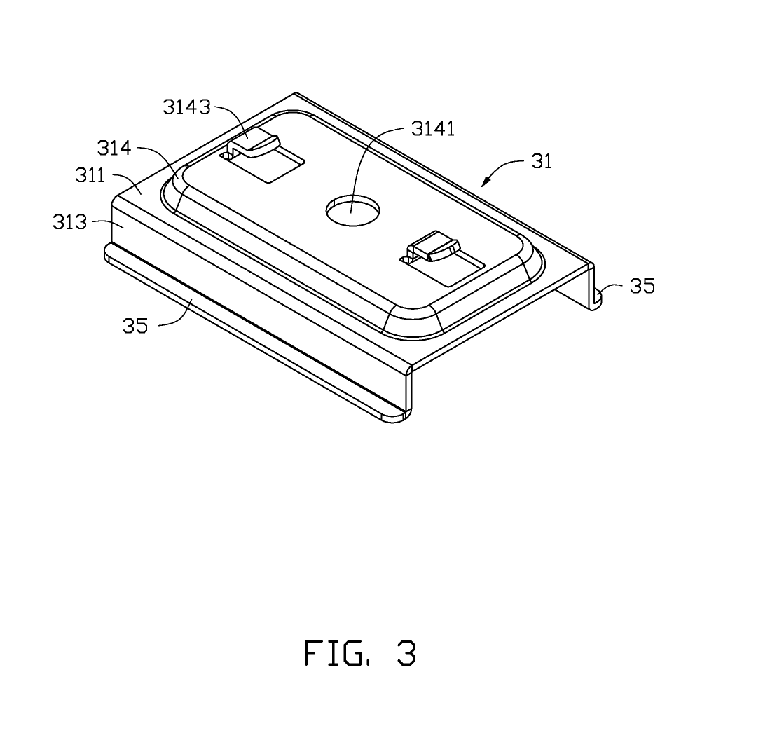

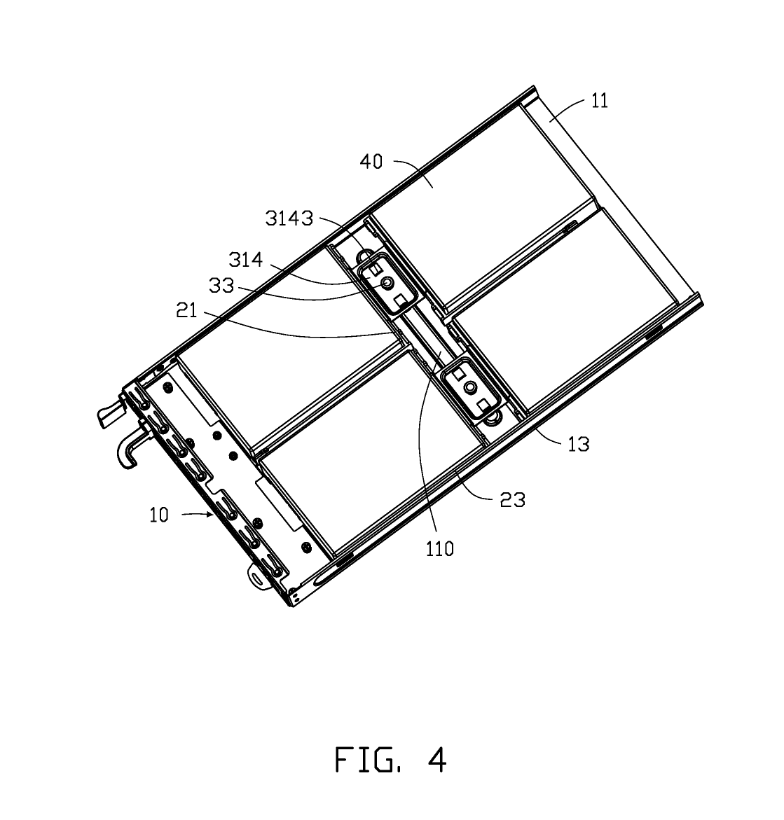

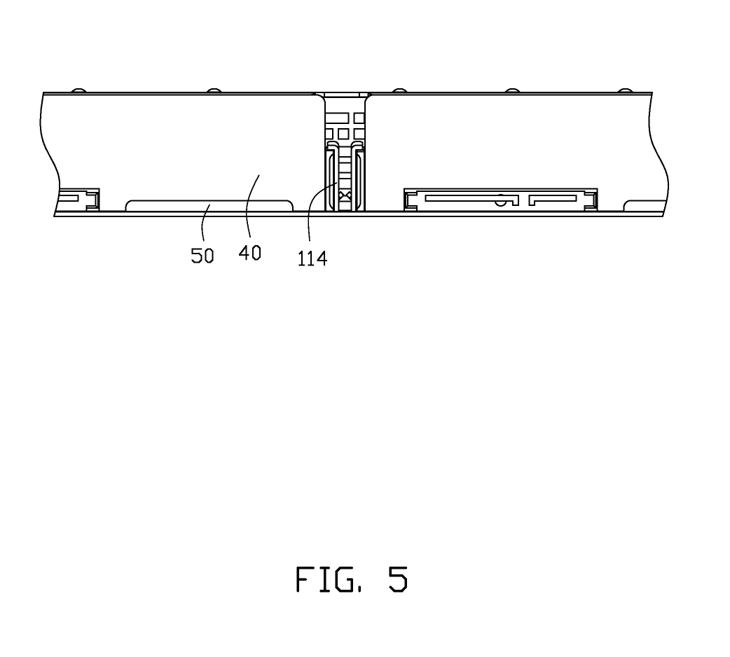

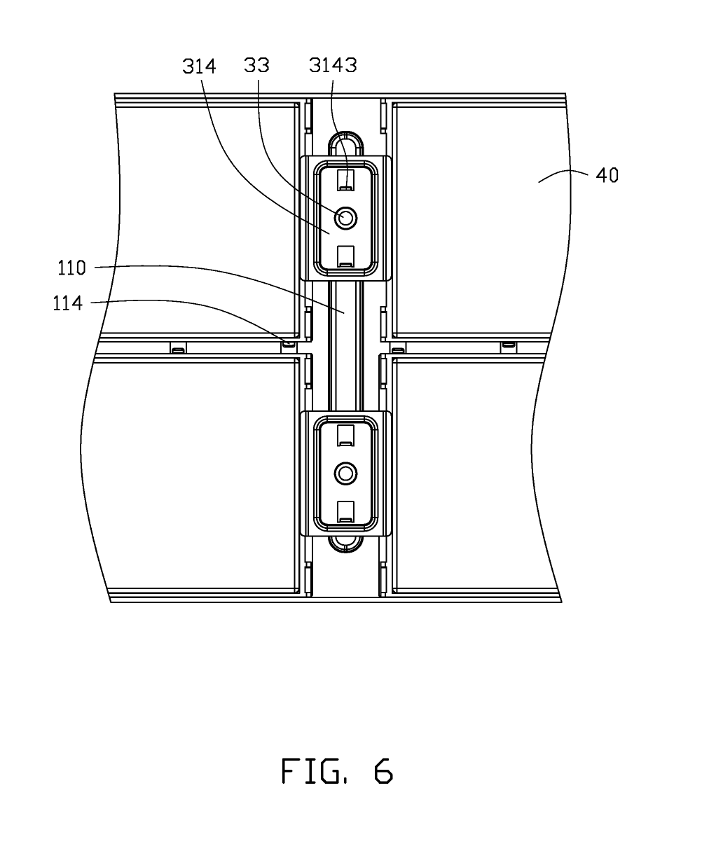

FIGS. 3-6 illustrates that in assembly, the two side panels 23 are deformed in opposite directions. The two side panels 23 can be deformed by engaging the plurality of mounting posts 231 in the corresponding mounting holes 41 securing the storage device 40 to the tray 20. The tray 20 can be placed on the bottom plate 11, and one of the two side panels 23 abuts against one of the two side plates 13. The tray 20 can be pushed in a first direction that is substantially parallel to the side plate 13, until the storage device 40 is blocked by the blocking member 50. At this time, the two side panels 23 are engaged with the first clipping portion 131 and the second clipping portion 114 respectively.

When four trays 20, each including a storage device 40, are positioned on the enclosure 10, each securing member 30 is located in the sliding passage 110. Each limiting portion 35 of the securing member 30 is engaged with a corresponding front panel 21, and the securing member 30 is slidable along the sliding passage 110 in a second direction that is substantially perpendicular to the side plate 13. When the through hole 3141 is aligned with the fixing portion 1123 and the two clamping pieces 3143 are clipped in the corresponding clamping holes 1121, the securing portion 33 is engaged in the through hole 3141, and the fixing portions 1123 secure the securing member 30 to the bottom plate 11 preventing the securing member 30 from moving. Therefore, the trays 20 with the storage devices 40 are secured in the enclosure 10.

In disassembly, the securing portion 33 is disengaged from the through hole 3141 and the fixing portions 1123. The securing member 30 is slid in the sliding passage 110 to disengage the clamping pieces 3143 from the clamping holes 1121. The securing member 30 is further slid detaching the limiting portions 35 from the front panel 21, and the trays 20 can be removed from the first clipping portions 131 and the second clipping portions 114. Therefore, the trays 20 with the storage devices 40 can be removed from the enclosure 10.

The embodiments shown and described above are only examples. Many details are often found in the art such as the other features of an enclosure. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A mounting apparatus comprising:
an enclosure comprising a side plate, and a fixing portion defined in the enclosure;
a tray configured to secure a first storage device, wherein the tray being slidable in a first direction that is substantially parallel to the side plate to engage with the side plate; and
a securing member comprises a first limiting portion and a securing portion;
wherein the first limiting portion is engaged with the tray, and the securing portion is engaged with the fixing portion to prevent the first limiting portion from disengaging from the tray.

2. The mounting apparatus of claim 1, wherein the enclosure defines a clamping hole, and the securing member further comprises a clamping portion engaged in the clamping hole.

3. The mounting apparatus of claim 1, wherein the tray comprises a front panel, the securing member further comprises a main body, and the first limiting portion extending from the main body and engaged with the front panel.

4. The mounting apparatus of claim 3, wherein the enclosure comprises a bottom plate coupled to the side plate, the tray comprises two side panels coupled to the front panel, and the two side panels are secured to the bottom plate and the side plate.

5. The mounting apparatus of claim 4, wherein the side plate comprises a first clipping portion, the bottom plate comprises a second clipping portion, and the first clipping portion and the second clipping portion are clipped with the two side panels.

6. The mounting apparatus of claim 4, wherein the fixing portion is a fixing hole that is defined in the bottom plate.

7. The mounting apparatus of claim 4, wherein the bottom plate defines a sliding passage that is substantially perpendicular to the side plate, and the securing member comprises a sliding portion slidably received in the sliding passage.

8. The mounting apparatus of claim 1, wherein a blocking member is located in the enclosure, and the blocking member is configured for abutting the first storage device.

9. A mounting apparatus comprising:
an enclosure comprising a bottom plate; a sliding passage defined in the bottom plate, and a fixing portion located in the sliding passage;
two trays attached to the bottom plate and located on opposite sides of the sliding passage; the two trays configured to secure two storage devices; a securing member comprising a securing portion and two limiting portions; wherein the securing member is slidably received in the sliding passage, the two limiting portions are engaged with the two trays, and the securing portion is engaged with the fixing portion to prevent the two limiting portions from disengaging from the two trays.

10. The mounting apparatus of claim 9, wherein the enclosure defines a clamping hole, and the securing member further comprises a clamping portion engaged in the clamping hole.

11. The mounting apparatus of claim 9, wherein each tray comprises a front panel, the securing member further comprises a main body, and the two limiting portions extending from the main body and engaged with the front panel.

12. The mounting apparatus of claim 11, wherein the enclosure comprises a bottom plate and a side plate coupled to the bottom plate, each tray comprises two side panels coupled to the front panel, and the two side panels are secured to the bottom plate and the side plate.

13. The mounting apparatus of claim 12, wherein the side plate comprises a first clipping portion, the bottom plate comprises a second clipping portion, and the first clipping portion and the second clipping portion are clipped with the two side panels.

14. The mounting apparatus of claim 12, wherein the fixing portion is a fixing hole that is defined in the bottom plate.

15. The mounting apparatus of claim 9, wherein a blocking member is located in the enclosure, and the blocking member is configured for abutting the storage devices.
